(19) United States
(12) Patent Application Publication
(10) Pub. No.: US 2024/0192597 A1
(43) Pub. Date: Jun. 13, 2024

(54) POLYMER, PHOTOSENSITIVE COMPOSITION, DRY FILM PHOTORESIST, AND LITHOGRAPHY METHOD

(71) Applicant: INDUSTRIAL TECHNOLOGY RESEARCH INSTITUTE, Hsinchu (TW)

(72) Inventors: Yu-Ying HSU, Hsinchu City (TW); Yao-Jheng HUANG, Taipei City (TW); Ming-Tzung WU, Mailiao Township (TW); Chin-Hua CHANG, Sanwan Township (TW); Te-Yi CHANG, Taoyuan City (TW)

(73) Assignee: INDUSTRIAL TECHNOLOGY RESEARCH INSTITUTE, Hsinchu (TW)

(21) Appl. No.: 18/493,972

(22) Filed: Oct. 25, 2023

Related U.S. Application Data
(63) Continuation-in-part of application No. 18/172,450, filed on Feb. 22, 2023, now abandoned.

(30) Foreign Application Priority Data
Oct. 25, 2022 (TW) 111140376
Aug. 8, 2023 (TW) 112129667

(51) Int. Cl. G03F 7/039; C08G 59/16; C08G 59/24; C08G 59/42; C08G 59/62; G03F 7/32

(52) U.S. Cl. CPC G03F 7/0392; C08G 59/1455; C08G 59/245; C08G 59/4238; C08G 59/628; G03F 7/322

(57) ABSTRACT

A polymer is formed by a reaction of phenolic epoxy resin or bisphenol epoxy resin and carboxylic acid, wherein the phenolic epoxy resin has a chemical structure of

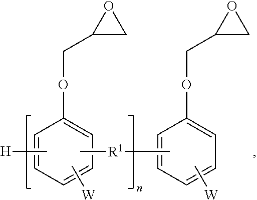

wherein W is H, alkyl group, or halogen. R¹ is methylene, methylene diphenyl, dimethylene benzene, tetrahydrodicyclopentadiene, or

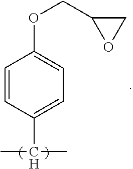

n=1 to 8. The bisphenol epoxy resin has a chemical structure of

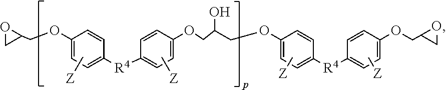

wherein Z is H or alkyl group; R⁴ is methylene, methylmethylene, dimethylmethylene, ethylmethylmethylene, bi(trifluoromethyl)methylene, fluorenylidene, or sulfonyl group; and p=1 to 10. The carboxylic acid has a chemical structure of HOOC—Ar—(—X)ₘ, HOOC—R², or a combination thereof, wherein Ar is benzene or naphthalene; X is hydroxy group, alkoxy group, or alkyl group, and at least one X is hydroxy group; m=1 to 3, wherein R² is C₃₋₇ alkyl group.

### CROSS REFERENCE TO RELATED APPLICATIONS

This application is a Continuation-In-Part of pending U.S. patent application Ser. No. 18/172,450, filed Feb. 22, 2023 and entitled “Polymer, photosensitive composition, dry film photoresist, and lithography method”, which is based on, and claims priority from, Taiwan Application Serial No. 111140376, filed on Oct. 25, 2022. This application also claims priority from Taiwan Application Serial No. 112129667, filed on Aug. 8, 2023. The disclosure of which is hereby incorporated by reference herein in its entirety.

### TECHNICAL FIELD

The technical field relates to a polymer, and in particular it relates to the application of the polymer in a photosensitive composition.

### BACKGROUND

The photoresist utilized in lithography processes are generally divided into positive photoresist and negative photoresist. Most positive photoresist is coated using a wet process and developed using a tetramethyl ammonium hydroxide (TMAH) solution, which cannot be used in a printed circuit board (PCB) process. Negative photoresists can be manufactured as dry film photoresists, which can be developed using a sodium carbonate solution. As such, negative photoresists can be used in the PCB process, but the resolution after development is deteriorated.

Accordingly, a novel photoresist composition is called for to form a positive dry film photoresist that can be developed using a sodium carbonate solution for use in a PCB process.

### SUMMARY

One embodiment of the disclosure provides a polymer formed by a reaction of phenolic epoxy resin or bisphenol epoxy resin and carboxylic acid, wherein the phenolic epoxy resin has a chemical structure of

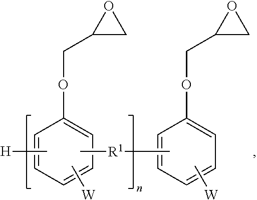

wherein W is H, alkyl group, or halogen; R¹ is methylene, dimethylene diphenyl, dimethylene benzene, tetrahydro dicyclopentadiene, or

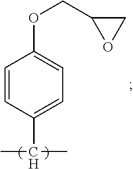

and n=1 to 8; wherein the bisphenol epoxy resin has a chemical structure of

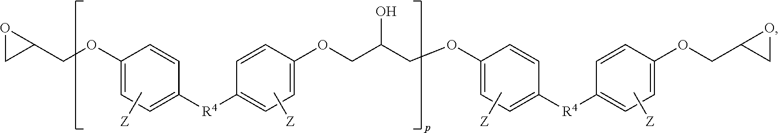

wherein Z is H or alkyl group; R⁴ is methylene, methylmethylene, dimethylmethylene, ethylmethylmethylene, bi(trifluoromethyl)methylene, fluorenylidene, or sulfonyl group; and p=1 to 10; wherein the carboxylic acid has a chemical structure of HOOC—Ar—(—X)ₘ, HOOC—R², or a combination thereof, wherein Ar is benzene or naphthalene; X is hydroxy group, alkoxy group, or alkyl group, and at least one X is hydroxy group; m=1 to 3; and wherein R² is C₃₋₇ alkyl group.

One embodiment of the disclosure provides a photosensitive composition, including: 100 parts by weight of the polymer; and 15 to 90 parts by weight of a photosensitive compound.

One embodiment of the disclosure provides a dry film photoresist, including a photosensitive film interposed between a support film and a protection film, wherein the photosensitive film includes the photosensitive composition.

One embodiment of the disclosure provides a lithography method, including the following steps: providing a material layer; forming a photoresist layer on the material layer, wherein the photoresist layer includes the photosensitive composition; exposing the photoresist layer so that the photoresist layer has an exposed part and an unexposed part; and developing the photoresist layer using an alkaline solution to remove the exposed part of the photoresist layer while keeping the unexposed part of the photoresist layer, thereby exposing a part of the material layer.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides a polymer formed by a reaction of phenolic epoxy resin or bisphenol epoxy resin and carboxylic acid, wherein the phenolic epoxy resin has a chemical structure of

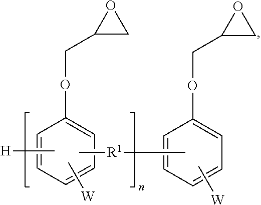

wherein W is H, alkyl group, or halogen. R¹ is methylene (—CH₂—), dimethylene diphenyl

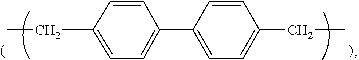

dimethylene benzene

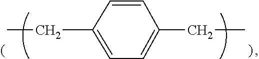

tetrahydrodicyclopentadiene

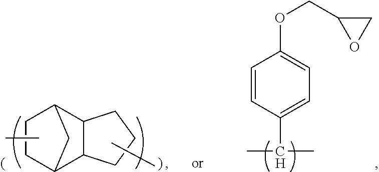

n=1 to 8. If n is too large, the solubility and the development resolution of the photosensitive composition including the polymer will be lowered. The bisphenol epoxy resin has a chemical structure of

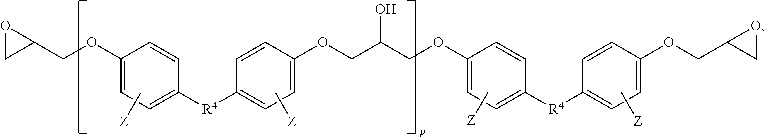

wherein Z is H or alkyl group; R⁴ is methylene, methylmethylene (—CH(CH₃)—), dimethylmethylene (—C(CH₃)₂—) , ethylmethylmethylene (—C(CH₃)(C₂H₅)—), bi(trifluoromethyl)methylene (—C(CF₃)₂—), fluorenylidene

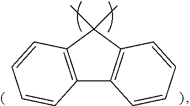

or sulfonyl group (—SO₂—); and p=1 to 10. If p is too large, the solubility and the development resolution of the photosensitive composition including the polymer will be lowered. The carboxylic acid has a chemical structure of HOOC—Ar—(—X)ₘ, HOOC—R², or a combination thereof. Ar is benzene or naphthalene. X is hydroxy group, alkoxy group, or alkyl group, and at least one X is hydroxy group, m=1 to 3, wherein R² is C₃₋₇ alkyl group. If Ar is free of hydroxy group, the image on the mask cannot be transferred on the polymer utilized as a positive dry film photoresist. If the carbon number of R² is too small or too large, the image on the mask cannot be transferred onto the polymer utilized as a positive dry film photoresist.

In some embodiments, the phenolic epoxy resin is cresol-based phenolic epoxy resin, biscresol-based phenolic epoxy resin, tricresol-based phenolic epoxy resin, or a combination thereof. In some embodiments, the bisphenol epoxy resin is bisphenol A epoxy resin, bispheol E epoxy resin, bisphenol F epoxy resin, bisphenol B epoxy resin, bisphenol AF epoxy resin, bisphenol S epoxy resin, or a combination thereof. In some embodiments, the carboxylic acid is hydroxy aromatic acid such as hydroxybenzoic acid, dihydroxybenzoic acid, trihydroxybenzoic acid, hydroxynaphthoic acid, or a combination thereof.

In some embodiments, the polymer has a chemical structure of

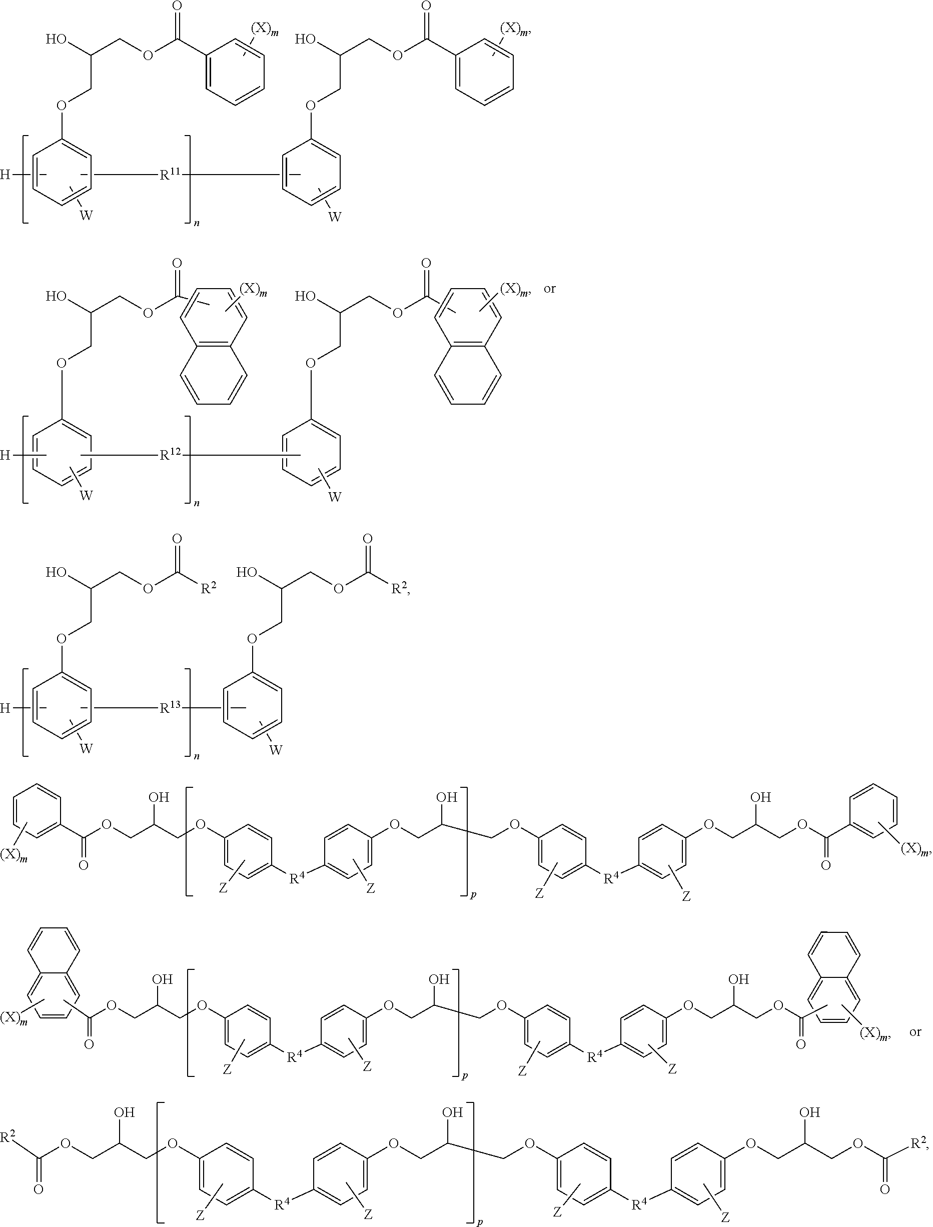

wherein R¹¹ is methylene, dimethylene diphenyl, dimethylene benzene, tetrahydrodicyclopentadiene, or

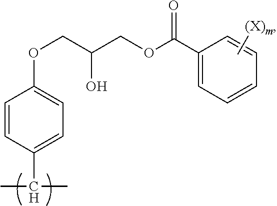

R¹² is methylene, dimethylene diphenyl, dimethylene benzene, tetrahydrodicyclopentadiene, or

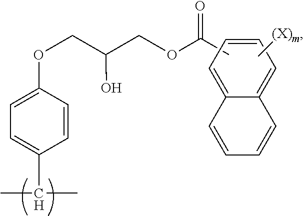

and R¹³ is methylene, dimethylene diphenyl, dimethylene benzene, tetrahydrodicyclopentadiene, or

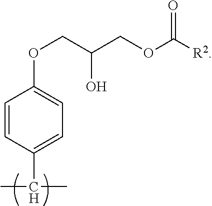

In some embodiments, the polymer is further reacted with anhydride to form a modified polymer, wherein the anhydride has a chemical structure of

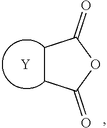

wherein Y is

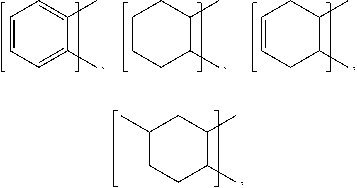

or a combination thereof, and the modified polymer has an acid value of 0 to 100 mg KOH/g. If the acid value of the modified polymer is too high, the photosensitive composition cannot be resistant to development. In some embodiments, the anhydride is hexahydrophthalic anhydride, tetrahydrophthalic anhydride, phthalic anhydride, or a combination thereof. In some embodiments, the polymer or the modified polymer has a weight average molecular weight of 2000 to 50000. If the weight average molecular weight of the polymer or the modified polymer is too low, the photosensitive composition cannot be formed as a film.

In some embodiments, the modified polymer has a chemical structure of

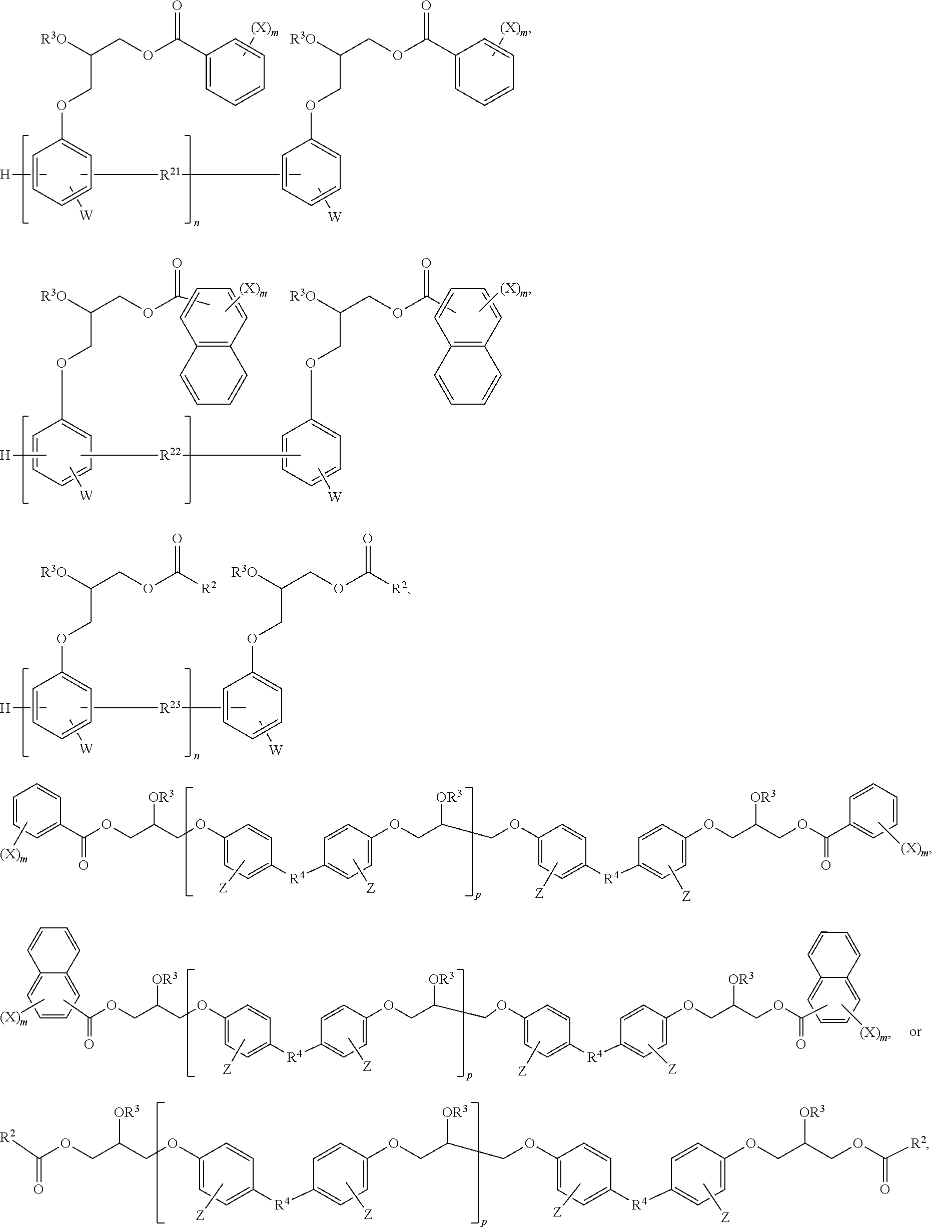

wherein R²¹ is methylene, dimethylene diphenyl, dimethylene benzene, tetrahydrodicyclopentadiene, or

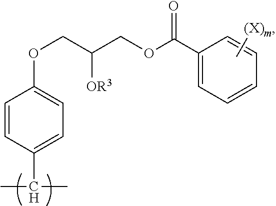

R²² is methylene, dimethylene diphenyl, dimethylene benzene, tetrahydrodicyclopentadiene, or

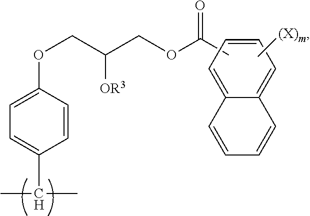

and R²³ is methylene, dimethylene diphenyl, dimethylenebenzene, tetrahydrodicyclopentadiene, or

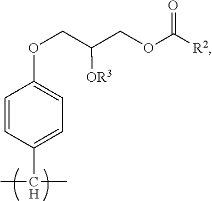

### and R³ is

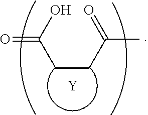

One embodiment of the disclosure provides a photosensitive composition, including: 100 parts by weight of the polymer; and 15 to 90 parts by weight of a photosensitive compound. If the photosensitive compound amount is too low, the photosensitivity of the photosensitive composition will be insufficient and the photosensitive composition cannot be resistant to the development. If the photosensitive compound amount is too high, the solubility and the develop-ability of the photosensitive composition will be poor. In some embodiments, the photosensitive compound includes a diazonaphthoquinone-based compound.

In some embodiments, the photosensitive composition further includes 200 to 1000 parts by weight of solvent. If the solvent amount is too low, the polymer and the photosensitive compound cannot be uniformly dispersed in the solvent, and the photoresist layer (formed by coating and drying the photosensitive composition) may have a non-uniform composition. If the solvent amount is too high, the cost for subsequently removing the solvent will be increased, and thick photoresist layer will be difficult to form. In some embodiments, the solvent includes propylene glycol monomethyl ether acetate, n-butyl acetate, ethyl acetate, γ-butyrolactone, cyclohexanone, or a combination thereof.

In some embodiments, the photosensitive composition may further includes 40 to 200 parts by weight of phenolic resin. The phenolic resin can be cresol-based, biscresol-based, tricresol-based, or a combination thereof. If the phenolic resin amount is too high, the develop-ability of the photosensitive composition will be poor. The phenolic resin may have a weight average molecular weight of 5000 to 50000. If the weight average molecular weight of the phenolic resin is too low, the photosensitive composition cannot be formed as a film. If the weight average molecular weight of the phenolic resin is too high, the photosensitive composition cannot be developed.

One embodiment of the disclosure provides a dry film photoresist, including a photosensitive film interposed between a support film and a protection film, wherein the photosensitive film includes the photosensitive composition. The support film has a release force of 150 g to 500 g, and the protection film has a release force of 1 g to 100 g. In some embodiments, the photosensitive film may have a thickness of 6 micrometers to 18 micrometers, which depends on the required thickness of the photoresist layer in the real lithography process.

For example, the solution of the photosensitive composition can be coated on the support film and dried, and the protection layer can be attached onto the dried photosensitive composition (photosensitive film), thereby forming the positive dry film photoresist. During the transferring process, the protection film is peeled off, and the dried photosensitive composition (photosensitive film) is attached to the material layer such as a wafer or a copper clad laminate. A heated roller is used to apply a pressure to the support film to transfer the dried photosensitive composition (photosensitive film) onto the material layer. The support film is then peeled off to perform subsequent exposure and development processes.

One embodiment of the disclosure provides a lithography method, including the following steps: providing a material layer; forming a photoresist layer on the material layer, and the photoresist layer includes the photosensitive composition. The method of forming the photoresist layer can be wet coating, or transferring the photoresist film in the described positive dry film photoresist onto the material layer. The photoresist layer is exposed to ensure that the photoresist layer has an exposed part and an unexposed part. The photoresist layer is developed using an alkaline solution to remove the exposed part of the photoresist layer while keeping the unexposed part of the photoresist layer, thereby exposing a part of the material layer. In some embodiments, the alkaline solution is sodium carbonate solution, sodium hydroxide solution, potassium hydroxide solution, or a combination thereof. Note that no positive dry film photoresist can be developed using a sodium carbonate solution before the disclosure. In some embodiments, the method further includes etching the exposed part of the material layer, implanting the exposed part of the material layer, or depositing another material layer on the exposed part of the material layer. For example, the material layer can be a substrate material, or a conductive layer, a dielectric layer, or a semiconductor layer formed on the substrate.

Below, exemplary embodiments will be described in detail so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

In the following Examples, the phenolic epoxy resin was commercially available from Nippon Kayaku. The bisphenol epoxy resin was EPON 828 (commercially available form Shell Chemical). The catalyst was chromium(III) acetylacetonate-triphenyl phosphite. The inhibitor was hydro quinone (abbreviated as HQ). The weight average molecular weight of the polymer was measured by GPC, in which the standard sample was polystyrene. The photosensitive compound was 2,3,4-trihydroxybenzo phenone naphthoquinone-1,2-diazido-5 sulfonate (abbreviated as DNQ).

For forming the positive dry film photoresist, the support film was a PET film having a release force of 300 g (commercially available from Nanya Plastics Co. or Shinkong Synthetic Fibers Co.), and the protection film was a PET film having a release force of 30 g (commercially available from Nanya Plastics Co. or Shinkong Synthetic Fibers Co.). A solution of the photosensitive composition was coated onto the support film, and then dried to form a photosensitive film (i.e. the dried photosensitive composition). The protection film was then attached onto the photosensitive film to form the positive dry film photoresist. During the transferring process, the protection film was peeled off, and the photosensitive film was attached to a wafer, and a pressure of 2.5 kg/cm² was applied to the support film by a roller at 95° C., such that the photosensitive film was transferred to the wafer. The support film was then peeled off to perform subsequent exposure and development processes.

### Example 1

24.4 g of phenolic epoxy resin EPPN-502H (commercially available from Nippon Kayaku), 20.1 g of 4-hydroxy benzoic acid (4-HBA), 0.13 g of catalyst, 0.04 g of HQ, and 47 g of propylene glycol monomethyl ether acetate (PGMEA) were mixed in a reaction bottle. The mixture was heated to 140° C. and stirred to react for 7 hours to form a polymer. Subsequently, 8.3 g of hexahydrophthalic anhydride was added to the reaction bottle, and then stirred to react for 3 hours to form a modified polymer. The modified polymer had an acid value of 83 mg KOH/g and a weight average molecular weight of 6500. The phenolic epoxy resin EPPN-502H has a chemical structure of

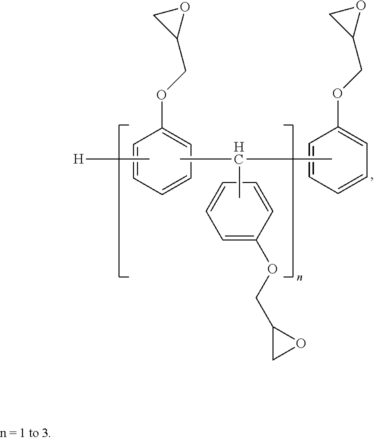

23 parts by weight of the modified polymer, 6.9 parts by weight of DNQ, and 70.1 parts by weight of a solvent (PGMEA and n-butyl acetate (BA), v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 20 seconds to 40 seconds. As such, a pattern having a resolution of 8 micrometers was obtained.

### Example 2

25.0 g of phenolic epoxy resin EPPN-502H, 20.6 g of 4-HBA, 0.14 g of catalyst, 0.04 g of HQ, and 48 g of PGMEA were mixed in a reaction bottle. The mixture was heated to 140° C. and stirred to react for 7 hours to form a polymer. Subsequently, 6.2 g of hexahydrophthalic anhydride was added to the reaction bottle, and then stirred to react for 3 hours to form a modified polymer. The modified polymer had an acid value of 58 mg KOH/g and a weight average molecular weight of 5200.

23 parts by weight of the modified polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 30 seconds to 50 seconds. As such, a pattern having a resolution of 8 micrometers was obtained.

### Example 3

25.7 g of phenolic epoxy resin EPPN-502H, 21.2 g of 4-HBA, 0.14 g of catalyst, 0.04 g of HQ, and 49.4 g of PGMEA were mixed in a reaction bottle. The mixture was heated to 140° C. and stirred to react for 7 hours to form a polymer. Subsequently, 3.5 g of hexahydrophthalic anhydride was added to the reaction bottle, and then stirred to react for 3 hours to form a modified polymer. The modified polymer had an acid value of 50 mg KOH/g and a weight average molecular weight of 5300.

23 parts by weight of the modified polymer, 8 parts by weight of DNQ, and 69 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 30 seconds to 50 seconds. As such, a pattern having a resolution of 8 micrometers was obtained.

### Example 4

30.0 g of phenolic epoxy resin EPPN-502H, 24.8 g of 4-HBA, 0.03 g of catalyst, 0.06 g of HQ, and 45 g of PGMEA were mixed in a reaction bottle. The mixture was heated to 140° C. and stirred to react for 7 hours to form a polymer. The polymer had an acid value of 27 mg KOH/g and a weight average molecular weight of 5700.

23 parts by weight of the polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 5

27.3 g of phenolic epoxy resin EPPN-502H, 22.5 g of 4-HBA, 0.14 g of catalyst, 0.04 g of HQ, and 50 g of PGMEA were mixed in a reaction bottle. The mixture was heated to 140° C. and stirred to react for 7 hours to form a polymer. The polymer had an acid value of 0 mg KOH/g and a weight average molecular weight of 5500.

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 30 seconds to 50 seconds. As such, a pattern having a resolution of 8 micrometers was obtained.

### Example 6

24.6 g of phenolic epoxy resin EPPN-502H, 20.3 g of 3-hydroxy benzoic acid (3-HBA), 0.13 g of catalyst, 0.04 g of HQ, and 45.2 g of PGMEA were mixed in a reaction bottle. The mixture was heated to 140° C. and stirred to react for 7 hours to form a polymer. Subsequently, 9.8 g of hexahydrophthalic anhydride was added to the reaction bottle, and then stirred to react for 3 hours to form a modified polymer. The modified polymer had an acid value of 80 mg KOH/g and a weight average molecular weight of 2900.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 20 seconds to 40 seconds. As such, a pattern having a resolution of 8 micrometers was obtained.

### Example 7

24.5 g of phenolic epoxy resin EPPN-502H, 20.2 g of 3-HBA, 0.13 g of catalyst, 0.04 g of HQ, and 47.2 g of PGMEA were mixed in a reaction bottle. The mixture was heated to 140° C. and stirred to react for 7 hours to form a polymer. Subsequently, 8.0 g of hexahydrophthalic anhydride was added to the reaction bottle, and then stirred to react for 3 hours to form a modified polymer. The modified polymer had an acid value of 65 mg KOH/g and a weight average molecular weight of 3300.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 30 seconds to 50 seconds. As such, a pattern having a resolution of 8 micrometers was obtained.

### Example 8

26.2 g of phenolic epoxy resin EPPN-502H, 21.6 g of 3-HBA, 0.14 g of catalyst, 0.04 g of HQ, and 48 g of PGMEA were mixed in a reaction bottle. The mixture was heated to 140° C. and stirred to react for 7 hours to form a polymer. Subsequently, 4.0 g of hexahydrophthalic anhydride was added to the reaction bottle, and then stirred to react for 3 hours to form a modified polymer. The modified polymer had an acid value of 37 mg KOH/g and a weight average molecular weight of 2700.

23 parts by weight of the modified polymer, 3.5 parts by weight of DNQ, and 73.5 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 60 seconds to 80 seconds. As such, a pattern having a resolution of 8 micrometers was obtained.

### Example 9

30 g of phenolic epoxy resin EPPN-502H, 24.8 g of 3-HBA, 0.03 g of catalyst, 0.06 g of HQ, and 45 g of PGMEA were mixed in a reaction bottle. The mixture was heated to 140° C. and stirred to react for 7 hours to form a polymer. The polymer had an acid value of 7 mg KOH/g and a weight average molecular weight of 3000.

23 parts by weight of the polymer, 5.1 parts by weight of DNQ, and 71.9 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 100 seconds to 120 seconds. As such, a pattern having a resolution of 8 micrometers was obtained.

### Example 10

27.3 g of phenolic epoxy resin EPPN-502H, 22.5 g of 3-HBA, 0.14 g of catalyst, 0.04 g of HQ, and 50 g of PGMEA were mixed in a reaction bottle. The mixture was heated to 140° C. and stirred to react for 7 hours to form a polymer. The polymer had an acid value of 0 mg KOH/g and a weight average molecular weight of 2800.

23 parts by weight of the polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 11

24.5 g of phenolic epoxy resin EPPN-502H, 20.2 g of 2-hydroxy benzoic acid (2-HBA), 0.13 g of catalyst, 0.04 g of HQ, and 47.2 g of PGMEA were mixed in a reaction bottle. The mixture was heated to 140° C. and stirred to react for 7 hours to form a polymer. Subsequently, 8.0 g of hexahydrophthalic anhydride was added to the reaction bottle, and then stirred to react for 3 hours to form a modified polymer. The modified polymer had an acid value of 88 mg KOH/g and a weight average molecular weight of 3500.

23 parts by weight of the modified polymer, 6.9 parts by weight of DNQ, and 70.1 parts by weight of a solvent (PGMEA and BA, v/v=9/1) were mixed, and the solubility of DNQ was poor (precipitation was seen by eye). The solution of the photosensitive composition was prepared as a positive dry film photoresist, and then transferred onto a wafer to form a photoresist layer. The photoresist layer was exposed by ghi-line (with an exposure amount of 1000 mJ/cm²), and then developed using a 1% sodium carbonate solution for 100 seconds to 150 seconds. As such, a pattern having a resolution of 50 micrometers was obtained.

### Example 12

26 g of phenolic epoxy resin EPPN-502H, 23.8 g of 2,6-dihydroxy benzoic acid (2,6-DHBA), 0.14 g of catalyst, 0.04 g of HQ, and 50 g of PGMEA were mixed in a reaction bottle. The mixture was heated to 140° C. and stirred to react for 7 hours to form a polymer. The polymer had an acid value of 7 mg KOH/g and a weight average molecular weight of 46000.

23 parts by weight of the polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 1000 mJ/cm²), and then developed using a 1% sodium carbonate solution for 100 seconds to 150 seconds. As such, a pattern having a resolution of 50 micrometers was obtained.

### Example 13

26 g of phenolic epoxy resin EPPN-502H, 23.8 g of 2,4-dihydroxy benzoic acid (2,4-DHBA), 0.14 g of catalyst, 0.04 g of HQ, and 50 g of PGMEA were mixed in a reaction bottle. The mixture was heated to 140° C. and stirred to react for 7 hours to form a polymer. The polymer had an acid value of 49 mg KOH/g and a weight average molecular weight of 11000.

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 90 seconds to 120 seconds. As such, a pattern having a resolution of 50 micrometers was obtained.

### Example 14

26 g of phenolic epoxy resin EPPN-502H, 23.8 g of 3,5-dihydroxy benzoic acid (3,5-DHBA), 0.14 g of catalyst, 0.04 g of HQ, and 50 g of PGMEA were mixed in a reaction bottle. The mixture was heated to 140° C. and stirred to react for 7 hours to form a polymer. The polymer had an acid value of 9 mg KOH/g and a weight average molecular weight of 3000.

23 parts by weight of the polymer, 5.1 parts by weight of DNQ, and 71.9 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 90 seconds to 120 seconds. As such, a pattern having a resolution of 50 micrometers was obtained.

### Example 15

23.5 g of phenolic epoxy resin (EPPN-502H), 26.3 g of 3-hydroxy-2-naphthoic acid (3H2NA), 0.12 g of catalyst, 0.04 g of HQ, and 50 g of PGMEA were mixed in a reaction bottle. The mixture was heated to 140° C. and stirred to react for 7 hours to form a polymer. The polymer had an acid value of 52 mg KOH/g and a weight average molecular weight of 11800.

23 parts by weight of the polymer, 6.9 parts by weight of DNQ, and 70.1 parts by weight of a solvent (PGMEA and BA, v/v=9/1) were mixed, and the solubility of DNQ was poor (precipitation was seen by eye). The solution of the photosensitive composition was prepared as a positive dry film photoresist, and then transferred onto a wafer to form a photoresist layer. The photoresist layer was exposed by ghi-line (with an exposure amount of 1000 mJ/cm²), and then developed using a 1% sodium carbonate solution for 100 seconds to 150 seconds. As such, a pattern having a resolution of 50 micrometers was obtained.

### Example 16

40.2 g of phenolic epoxy resin EPPN-502H, 24.5 g of pentanoic acid, 0.06 g of catalyst, 0.07 g of HQ, and 35.2 g of PGMEA were mixed in a reaction bottle. The mixture was heated to 140° C. and stirred to react for 7 hours to form a polymer. The polymer had an acid value of 25 mg KOH/g and a weight average molecular weight of 2400.

12 parts by weight of the polymer, 10.2 parts by weight of phenolic resin PR56001 (having a weight average molecular weight of 5000, commercially available from Sumitomoto Bakelite), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 17

7.5 parts by weight of the polymer synthesized in Example 16, 15 parts by weight of phenolic resin PR56001 (having a weight average molecular weight of 5000), 6.7 parts by weight of DNQ, and 70.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 18

15 parts by weight of the polymer synthesized in Example 16, 7.5 parts by weight of phenolic resin PR56001 (having a weight average molecular weight of 5000), 3.5 parts by weight of DNQ, and 74.3 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 19

36.4 g of phenolic epoxy resin EPPN-502H, 22.2 g of pentanoic acid, 0.19 g of catalyst, 0.07 g of HQ, and 35.0 g of PGMEA were mixed in a reaction bottle. The mixture was heated to 140° C. and stirred to react for 7 hours to form a polymer. Subsequently, 6.1 g of hexahydrophthalic anhydride was added to the reaction bottle, and then stirred to react for 3 hours to form a modified polymer. The modified polymer had an acid value of 61 mg KOH/g and a weight average molecular weight of 2500.

12 parts by weight of the modified polymer, 10.2 parts by weight of phenolic resin PR56032 (having a weight average molecular weight of 50000, commercially available from Sumitomoto Bakelite), 8 parts by weight of DNQ, and 69.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 20

7.5 parts by weight of the polymer synthesized in Example 19, 15 parts by weight of phenolic resin PR56032 (having a weight average molecular weight of 50000), 6.7 parts by weight of DNQ, and 70.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 21

15 parts by weight of the polymer synthesized in Example 19, 7.5 parts by weight of phenolic resin PR56032 (having a weight average molecular weight of 50000), 6.7 parts by weight of DNQ, and 70.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 400 mJ/cm²), and then developed using a 1% sodium carbonate solution for 60 seconds to 90 seconds. As such, a pattern having a resolution of 8 micrometers was obtained.

### Example 22

40.2 g of phenolic epoxy resin EPPN-502H, 17.7 g of propanoic acid, 0.21 g of catalyst, 0.07 g of HQ, and 35.0 g of PGMEA were mixed in a reaction bottle. The mixture was heated to 140° C. and stirred to react for 7 hours to form a polymer. Subsequently, 6.7 g of hexahydrophthalic anhydride was added to the reaction bottle, and then stirred to react for 3 hours to form a modified polymer. The modified polymer had an acid value of 55 mg KOH/g and a weight average molecular weight of 2700.

12 parts by weight of the modified polymer, 10.2 parts by weight of phenolic resin PR56001 (having a weight average molecular weight of 5000), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Example 23

12 parts by weight of the modified polymer synthesized in Example 22, 10.2 parts by weight of phenolic resin PR56032 (having a weight average molecular weight of 50000), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Example 24

29 g of phenolic epoxy resin EPPN-502H, 21.1 g of benzoic acid, 0.15 g of catalyst, 0.06 g of HQ, and 40.0 g of PGMEA were mixed in a reaction bottle. The mixture was heated to 140° C. and stirred to react for 7 hours to form a polymer. Subsequently, 9.7 g of hexahydrophthalic anhydride was added to the reaction bottle, and then stirred to react for 3 hours to form a modified polymer. The modified polymer had an acid value of 80 mg KOH/g and a weight average molecular weight of 2500.

12 parts by weight of the modified polymer, 10.2 parts by weight of phenolic resin PR56001 (having a weight average molecular weight of 5000), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Example 25

12 parts by weight of the modified polymer synthesized in Example 24, 10.2 parts by weight of phenolic resin PR56032 (having a weight average molecular weight of 50000), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Example 26

31.5 g of phenolic epoxy resin EPPN-502H, 22.9 g of benzoic acid, 0.16 g of catalyst, 0.07 g of HQ, and 40.0 g of PGMEA were mixed in a reaction bottle. The mixture was heated to 140° C. and stirred to react for 7 hours to form a polymer. Subsequently, 5.3 g of hexahydrophthalic anhydride was added to the reaction bottle, and then stirred to react for 3 hours to form a modified polymer. The modified polymer had an acid value of 46 mg KOH/g and a weight average molecular weight of 2500.

12 parts by weight of the modified polymer, 10.2 parts by weight of phenolic resin PR56032 (having a weight average molecular weight of 50000), 6.7 parts by weight of DNQ, and 71.1 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Example 27

28.8 g of phenolic epoxy resin EPPN-201 (commercially available from Nippon Kayaku), 21 g of 4-HBA, 0.13 g of catalyst, 0.04 g of HQ, and 50 g of PGMEA were mixed in a reaction bottle. The mixture was heated to 140° C. and stirred to react for 7 hours to form a polymer. The polymer had an acid value of 0 mg KOH/g and a weight average molecular weight of 5200. The phenolic epoxy resin EPPN-201 has a chemical structure of

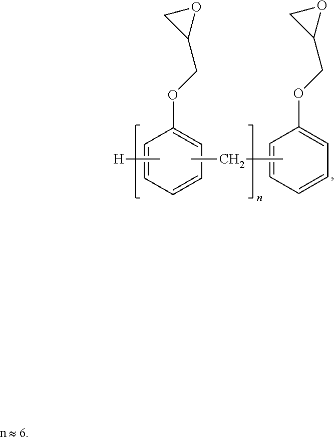

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 28

30.1 g of phenolic epoxy resin EOCN-102S (commercially available from Nippon Kayaku), 19.8 g of 4-HBA, 0.13 g of catalyst, 0.04 g of HQ, and 50 g of PGMEA were mixed in a reaction bottle. The mixture was heated to 140° C. and stirred to react for 7 hours to form a polymer. The polymer had an acid value of 3 mg KOH/g and a weight average molecular weight of 5600. The phenolic epoxy resin EOCN-102S has a chemical structure of

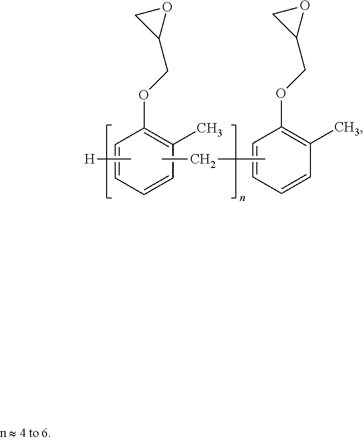

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 29

33.2 g of phenolic epoxy resin BREN-105 (commercially available from Nippon Kayaku), 16.7 g of 4-HBA, 0.11 g of catalyst, 0.04 g of HQ, and 50 g of PGMEA were mixed in a reaction bottle. The mixture was heated to 140° C. and stirred to react for 7 hours to form a polymer. The polymer had an acid value of 5 mg KOH/g and a weight average molecular weight of 5900. The phenolic epoxy resin BREN-105 has a chemical structure of

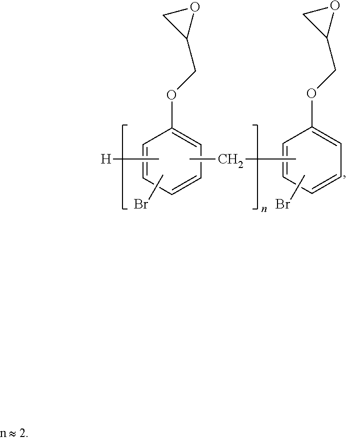

23 parts by weight of the polymer, 5.1 parts by weight of DNQ, and 71.9 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 30

32.2 g of phenolic epoxy resin XD-1000 (commercially available from Nippon Kayaku), 17.7 g of 4-HBA, 0.11 g of catalyst, 0.04 g of HQ, and 50 g of PGMEA were mixed in a reaction bottle. The mixture was heated to 140° C. and stirred to react for 7 hours to form a polymer. The polymer had an acid value of 5 mg KOH/g and a weight average molecular weight of 5700. The phenolic epoxy resin XD-1000 has a chemical structure of

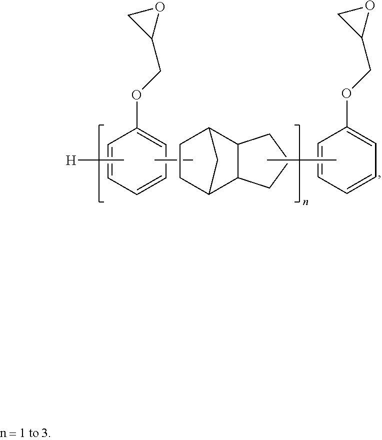

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 60 seconds to 80 seconds. As such, a pattern having a resolution of 8 micrometers was obtained.

### Example 31

31.4 g of phenolic epoxy resin NC-2000-L (commercially available from Nippon Kayaku), 18.5 g of 4-HBA, 0.12 g of catalyst, 0.04 g of HQ, and 50 g of PGMEA were mixed in a reaction bottle. The mixture was heated to 140° C. and stirred to react for 7 hours to form a polymer. The polymer had an acid value of 3 mg KOH/g and a weight average molecular weight of 5100. The phenolic epoxy resin NC-2000-L has a chemical structure of

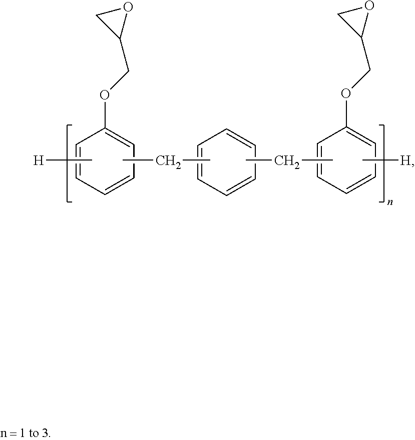

23 parts by weight of the polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 60 seconds to 80 seconds. As such, a pattern having a resolution of 8 micrometers was obtained.

### Example 32

33.0 g of phenolic epoxy resin NC-3000-L (commercially available from Nippon Kayaku), 16.9 g of 4-HBA, 0.11 g of catalyst, 0.04 g of HQ, and 50 g of PGMEA were mixed in a reaction bottle. The mixture was heated to 140° C. and stirred to react for 7 hours to form a polymer. The polymer had an acid value of 5 mg KOH/g and a weight average molecular weight of 6000. The phenolic epoxy resin NC-3000-L has a chemical structure of

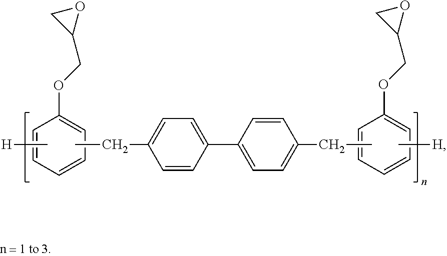

23 parts by weight of the polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 33

30.2 g of phenolic epoxy resin NC-7300L (commercially available from Nippon Kayaku), 19.6 g of 4-HBA, 0.13 g of catalyst, 0.04 g of HQ, and 50 g of PGMEA were mixed in a reaction bottle. The mixture was heated to 140° C. and stirred to react for 7 hours to form a polymer. The polymer had an acid value of 4 mg KOH/g and a weight average molecular weight of 5800. The phenolic epoxy resin NC-7300L has a chemical structure of

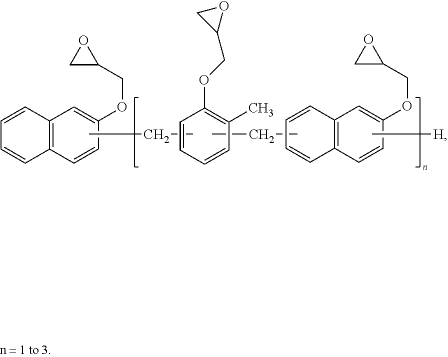

23 parts by weight of the polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 34

26.5 g of phenolic epoxy resin EPPN-201, 19.3 g of 4-HBA, 0.12 g of catalyst, 0.04 g of HQ, and 46.0 g of PGMEA were mixed in a reaction bottle. The mixture was heated to 140° C. and stirred to react for 7 hours to form a polymer. Subsequently, 8 g of hexahydrophthalic anhydride was added to the reaction bottle, and then stirred to react for 3 hours to form a modified polymer. The modified polymer had an acid value of 82 mg KOH/g and a weight average molecular weight of 6100.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 35

27.8 g of phenolic epoxy resin EOCN-102S, 18.3 g of 4-HBA, 0.12 g of catalyst, 0.04 g of HQ, and 46.2 g of PGMEA were mixed in a reaction bottle. The mixture was heated to 140° C. and stirred to react for 7 hours to form a polymer. Subsequently, 7.5 g of hexahydrophthalic anhydride was added to the reaction bottle, and then stirred to react for 3 hours to form a modified polymer. The modified polymer had an acid value of 83 mg KOH/g and a weight average molecular weight of 6500.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 36

31.1 g of phenolic epoxy resin BREN-105, 15.6 g of 4-HBA, 0.10 g of catalyst, 0.04 g of HQ, and 46.8 g of PGMEA were mixed in a reaction bottle. The mixture was heated to 140° C. and stirred to react for 7 hours to form a polymer. Subsequently, 6.4 g of hexahydrophthalic anhydride was added to the reaction bottle, and then stirred to react for 3 hours to form a modified polymer. The modified polymer had an acid value of 80 mg KOH/g and a weight average molecular weight of 5900.

23 parts by weight of the modified polymer, 5.1 parts by weight of DNQ, and 71.9 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 70 seconds to 90 seconds. As such, a pattern having a resolution of 8 micrometers was obtained.

### Example 37

30.0 g of phenolic epoxy resin XD-1000, 16.5 g of 4-HBA, 0.11 g of catalyst, 0.04 g of HQ, and 46.6 g of PGMEA were mixed in a reaction bottle. The mixture was heated to 140° C. and stirred to react for 7 hours to form a polymer. Subsequently, 6.8 g of hexahydrophthalic anhydride was added to the reaction bottle, and then stirred to react for 3 hours to form a modified polymer. The modified polymer had an acid value of 80 mg KOH/g and a weight average molecular weight of 6700.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 60 seconds to 80 seconds. As such, a pattern having a resolution of 8 micrometers was obtained.

### Example 38

29.2 g of phenolic epoxy resin NC-2000-L, 17.2 g of 4-HBA, 0.11 g of catalyst, 0.04 g of HQ, and 46.4 g of PGMEA were mixed in a reaction bottle. The mixture was heated to 140° C. and stirred to react for 7 hours to form a polymer. Subsequently, 7.1 g of hexahydrophthalic anhydride was added to the reaction bottle, and then stirred to react for 3 hours to form a modified polymer. The modified polymer had an acid value of 82 mg KOH/g and a weight average molecular weight of 6300.

23 parts by weight of the modified polymer, 6.0 parts by weight of DNQ, and 71 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 60 seconds to 80 seconds. As such, a pattern having a resolution of 8 micrometers was obtained.

### Example 39

30.8 g of phenolic epoxy resin NC-3000-L, 15.8 g of 4-HBA, 0.10 g of catalyst, 0.04 g of HQ, and 46.8 g of PGMEA were mixed in a reaction bottle. The mixture was heated to 140° C. and stirred to react for 7 hours to form a polymer. Subsequently, 6.5 g of hexahydrophthalic anhydride was added to the reaction bottle, and then stirred to react for 3 hours to form a modified polymer. The modified polymer had an acid value of 78 mg KOH/g and a weight average molecular weight of 6500.

23 parts by weight of the modified polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 40

28.0 g of phenolic epoxy resin NC-7300L, 18.2 g of 4-HBA, 0.12 g of catalyst, 0.04 g of HQ, and 46.2 g of PGMEA were mixed in a reaction bottle. The mixture was heated to 140° C. and stirred to react for 7 hours to form a polymer. Subsequently, 7.5 g of hexahydrophthalic anhydride was added to the reaction bottle, and then stirred to react for 3 hours to form a modified polymer. The modified polymer had an acid value of 77 mg KOH/g and a weight average molecular weight of 6600.

23 parts by weight of the modified polymer, 6.9 parts by weight of DNQ, and 70.1 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 41

34.5 g of bisphenol epoxy resin EPON 828, 25.3 g of 4-HBA, 0.18 g of catalyst, 0.07 g of HQ, and 40.0 g of PGMEA were mixed in a reaction bottle. The mixture was heated to 140° C. and stirred to react for 7 hours to form a polymer. The polymer had an acid value of 3 mg KOH/g and a weight average molecular weight of 2100.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 42

18.3 parts by weight of the polymer of Example 41, 9.1 parts by weight of phenolic resin PR56001 (having a weight average molecular weight of 5000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 43

17.4 parts by weight of the polymer of Example 41, 8.7 parts by weight of phenolic resin PR56032 (having a weight average molecular weight of 50000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 44

18.3 parts by weight of the polymer of Example 41, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 45

26.1 parts by weight of the polymer of Example 41, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 46

27.4 parts by weight of the polymer of Example 41, 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 20 seconds to 40 seconds. As such, a pattern having a resolution of 8 micrometers was obtained.

### Example 47

28.2 g of bisphenol epoxy resin EPON 828, 20.7 g of 4-HBA, 0.15 g of catalyst, 0.07 g of HQ, and 40.0 g of PGMEA were mixed in a reaction bottle. The mixture was heated to 140° C. and stirred to react for 7 hours to form a polymer. Subsequently, 10.9 g of hexahydrophthalic anhydride was added to the reaction bottle, and then stirred to react for 3 hours to form a modified polymer. The modified polymer had an acid value of 81 mg KOH/g and a weight average molecular weight of 2800.

17.4 parts by weight of the modified polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 48

18.3 parts by weight of the modified polymer of Example 47, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 49

26.1 parts by weight of the modified polymer of Example 47, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 50

34.5 g of bisphenol epoxy resin EPON 828, 25.3 g of 3-HBA, 0.18 g of catalyst, 0.07 g of HQ, and 40.0 g of PGMEA were mixed in a reaction bottle. The mixture was heated to 140° C. and stirred to react for 7 hours to form a polymer. The polymer had an acid value of 0 mg KOH/g and a weight average molecular weight of 2300.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 51

18.3 parts by weight of the polymer of Example 50, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 52

26.1 parts by weight of the polymer of Example 50, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 53

28.2 g of bisphenol epoxy resin EPON 828, 20.7 g of 3-HBA, 0.15 g of catalyst, 0.07 g of HQ, and 40.0 g of PGMEA were mixed in a reaction bottle. The mixture was heated to 140° C. and stirred to react for 7 hours to form a polymer. Subsequently, 10.9 g of hexahydrophthalic anhydride was added to the reaction bottle, and then stirred to react for 3 hours to form a modified polymer. The modified polymer had an acid value of 77 mg KOH/g and a weight average molecular weight of 2900.

17.4 parts by weight of the modified polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 54

18.3 parts by weight of the modified polymer of Example 53, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 55

26.1 parts by weight of the modified polymer of Example 53, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 56

33.5 g of bisphenol epoxy resin EPON 828, 27.3 g of 2,6-DHBA, 0.18 g of catalyst, 0.07 g of HQ, and 38.9 g of PGMEA were mixed in a reaction bottle. The mixture was heated to 140° C. and stirred to react for 7 hours to form a polymer. The polymer had an acid value of 0 mg KOH/g and a weight average molecular weight of 2500.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 57

18.3 parts by weight of the polymer of Example 56, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 58

26.1 parts by weight of the polymer of Example 56, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 59

33.5 g of bisphenol epoxy resin EPON 828, 27.3 g of 2,4-DHBA, 0.18 g of catalyst, 0.07 g of HQ, and 38.9 g of PGMEA were mixed in a reaction bottle. The mixture was heated to 140° C. and stirred to react for 7 hours to form a polymer. The polymer had an acid value of 2 mg KOH/g and a weight average molecular weight of 2600.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 60

18.3 parts by weight of the polymer of Example 59, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 61

26.1 parts by weight of the polymer of Example 59, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 62

33.5 g of bisphenol epoxy resin EPON 828, 27.3 g of 3,5-DHBA, 0.18 g of catalyst, 0.07 g of HQ, and 38.9 g of PGMEA were mixed in a reaction bottle. The mixture was heated to 140° C. and stirred to react for 7 hours to form a polymer. The polymer had an acid value of 3 mg KOH/g and a weight average molecular weight of 2300.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 63

18.3 parts by weight of the polymer of Example 62, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 64

26.1 parts by weight of the polymer of Example 62, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 65

31.6 g of bisphenol epoxy resin EPON 828, 31.6 g of 3H2NA, 0.17 g of catalyst, 0.07 g of HQ, and 36.6 g of PGMEA were mixed in a reaction bottle. The mixture was heated to 140° C. and stirred to react for 7 hours to form a polymer. The polymer had an acid value of 0 mg KOH/g and a weight average molecular weight of 2800.

17.4 parts by weight of the polymer, 8.7 parts by weight of phenolic resin PR56001 (having a weight average molecular weight of 5000), 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Example 66

18.3 parts by weight of the polymer of Example 65, 9.1 parts by weight of phenolic resin PR56032 (having a weight average molecular weight of 50000), 4.8 parts by weight of DNQ, and 67.8 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 200 mJ/cm²), and then developed using a 1% sodium carbonate solution for 40 seconds to 60 seconds. As such, a pattern having a resolution of 8 micrometers was obtained.

### Example 67

26.1 parts by weight of the polymer of Example 65, 6.3 parts by weight of DNQ, and 67.6 parts by weight of a solvent (PGMEA and BA, v/v=9/1) were mixed, and the solubility of DNQ was good (no precipitation was seen by eye). The solution of the photosensitive composition was prepared as a positive dry film photoresist, and then transferred onto a wafer to form a photoresist layer. The photoresist layer was exposed by ghi-line (with an exposure amount of 100 mJ/cm²), and then developed using a 1% sodium carbonate solution for 40 seconds to 60 seconds. As such, a pattern having a resolution of 8 micrometers was obtained.

### Comparative Example 1

22.5 parts by weight of phenolic resin PR56001 (with a weight average molecular weight of 5000), 6.7 parts by weight of DNQ, and 70.8 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

### Comparative Example 2

22.5 parts by weight of phenolic resin PR56032 (with a weight average molecular weight of 50000), 6.7 parts by weight of DNQ, and 70.8 parts by weight of a solvent (PGMEA and BA, v/v=9/1) were mixed, and the solubility of DNQ was good (no precipitation was seen by eye). The solution of the photosensitive composition was prepared as a positive dry film photoresist, which could not be transferred onto a wafer to form a photoresist layer.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A polymer, formed by a reaction of phenolic epoxy resin or bisphenol epoxy resin and carboxylic acid,
wherein the phenolic epoxy resin has a chemical structure of 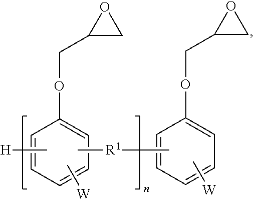
wherein W is H, alkyl group, or halogen; R¹ is methylene, dimethylene diphenyl, dimethylene benzene, tetrahydrodicyclopentadiene, or 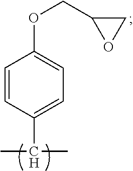
and n=1 to 8;
wherein the bisphenol epoxy resin has a chemical structure of 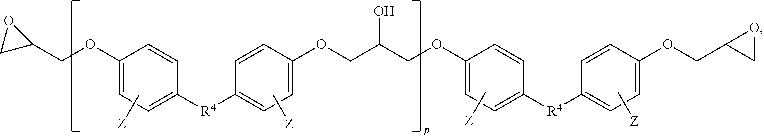
wherein Z is H or alkyl group; R⁴ is methylene, methylmethylene, dimethylmethylene, ethylmethylmethylene, bi(trifluoromethyl)methylene, fluorenylidene, or sulfonyl group; and p=1 to 10; wherein the carboxylic acid has a chemical structure of HOOC—Ar—(—X)ₘ, HOOC—R², or a combination thereof, wherein Ar is benzene or naphthalene; X is hydroxy group, alkoxy group, or alkyl group, and at least one X is hydroxy group; m=1 to 3; and wherein R² is C₃₋₇ alkyl group.

2. The polymer as claimed in claim 1, having a chemical structure of 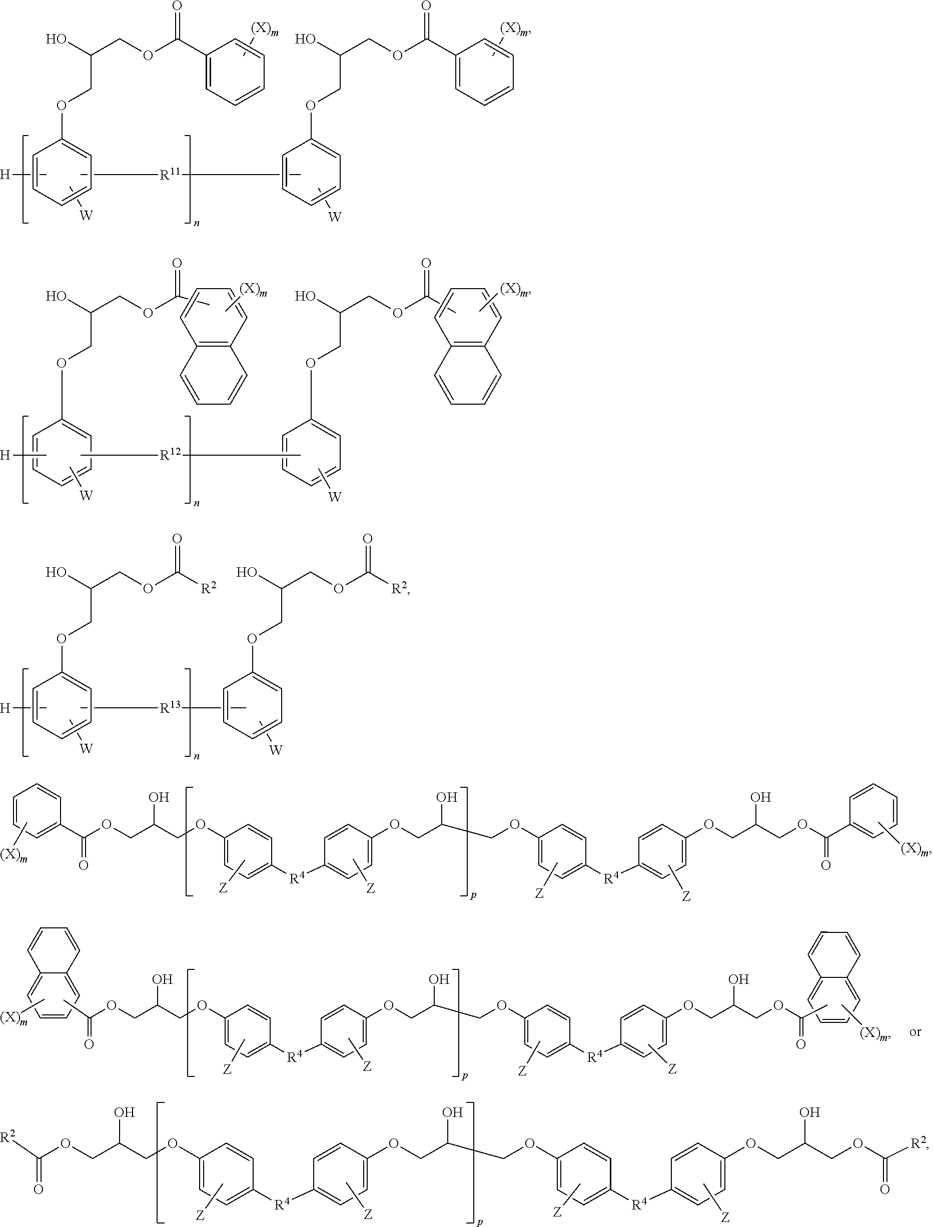
wherein R¹¹ is methylene, dimethylene diphenyl, dimethylene benzene, tetrahydrodicyclopentadiene, or 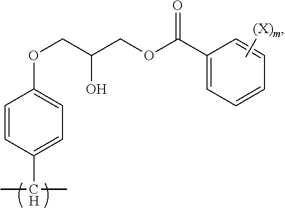
R¹² is methylene, dimethylene diphenyl, dimethylene benzene, tetrahydrodicyclopentadiene, or 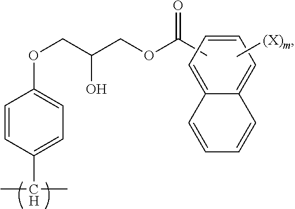
and R¹³ is methylene, dimethylene diphenyl, dimethylene benzene, tetrahydrodicyclopentadiene, or

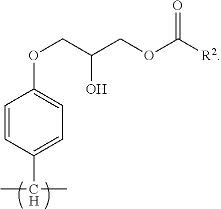

3. The polymer as claimed in claim 1, further reacted with anhydride to form a modified polymer, wherein the anhydride has a chemical structure of 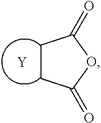
wherein Y is 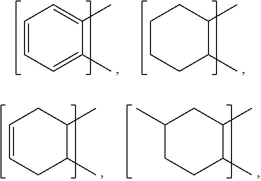
or a combination thereof, and the modified polymer has an acid value of 0 to 100 mg KOH/g.

4. The polymer as claimed in claim 3, wherein the modified polymer has a chemical structure of 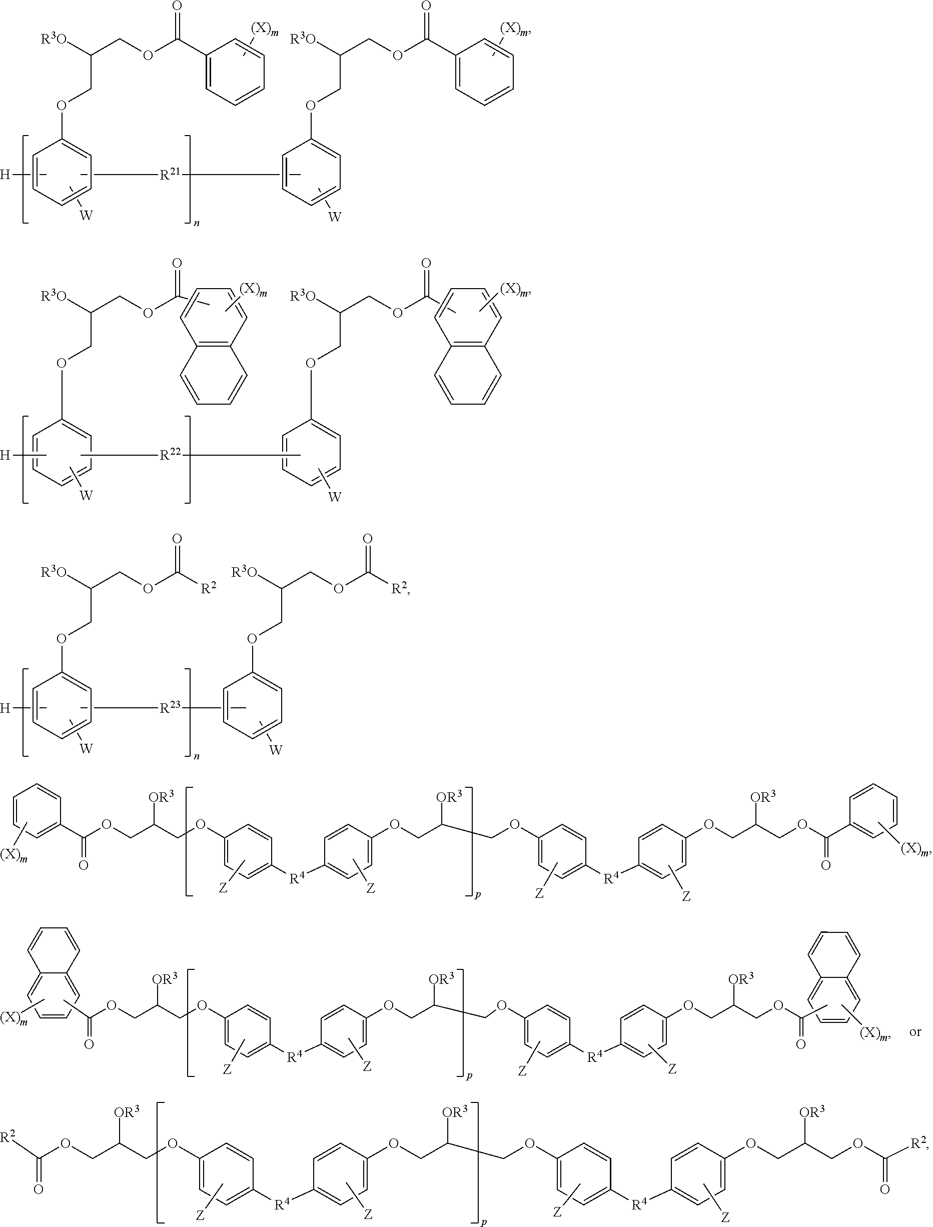
wherein R²¹ is methylene, dimethylene diphenyl, dimethylene benzene, tetrahydrodicyclopentadiene, or 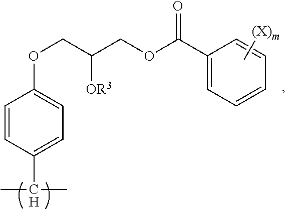
R²² is methylene, dimethylene diphenyl, dimethylene benzene, tetrahydrodicyclopentadiene, or 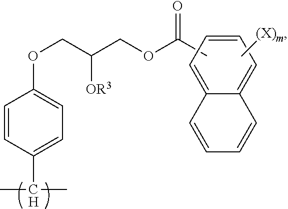
and R²³ is methylene, dimethylene diphenyl, dimethylene benzene, tetrahydrodicyclopentadiene, or 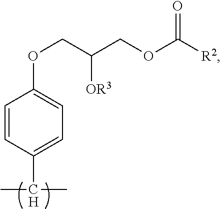
and R³ is

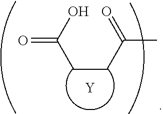

5. A photosensitive composition, comprising:
100 parts by weight of the polymer as claimed in claim 1; and
15 to 90 parts by weight of a photosensitive compound.

6. The photosensitive composition as claimed in claim 5, wherein the photosensitive compound comprises a diazonaphthoquinone-based compound.

7. The photosensitive composition as claimed in claim 5, further comprising 200 to 1000 parts by weight of a solvent.

8. The photosensitive composition as claimed in claim 7, wherein the solvent comprises propylene glycol monomethyl ether acetate, n-butyl acetate, ethyl acetate, γ-butyrolactone, cyclohexanone, or a combination thereof.

9. The photosensitive composition as claimed in claim 5, further comprising 40 to 200 parts by weight of phenolic resin.

10. A dry film photoresist, comprising:
a photosensitive film interposed between a support film and a protection film, wherein the photosensitive film comprises the photosensitive composition as claimed in claim 5.

11. The dry film photoresist as claimed in claim 10, wherein the protection film has a release force of 1 g to 100 g, and the support film has a release force of 150 g to 500 g.

12. A lithography method, comprising:
providing a material layer;
forming a photoresist layer on the material layer, and the photoresist layer comprises the photosensitive composition as claimed in claim 5;
exposing the photoresist layer to make the photoresist layer have an exposed part and an unexposed part; and
developing the photoresist layer using an alkaline solution to remove the exposed part of the photoresist layer while keeping the unexposed part of the photoresist layer, thereby exposing a part of the material layer.

13. The lithography method as claimed in claim 12, wherein the alkaline solution is a sodium carbonate solution, sodium hydroxide solution, potassium hydroxide solution, or a combination thereof.

14. The lithography method as claimed in claim 12, further comprising etching the exposed part of the material layer, implanting the exposed part of the material layer, or depositing another material layer on the exposed part of the material layer.
